(19) United States
(12) Patent Application Publication
(10) Pub. No.: US 2025/0306472 A1
(43) Pub. Date: Oct. 2, 2025

(54) METHOD FOR DETERMINING A FAILURE EVENT ON A LITHOGRAPHY SYSTEM AND ASSOCIATED FAILURE DETECTION MODULE

(71) Applicant: ASML NETHERLANDS B.V., Veldhoven (NL)

(72) Inventors: Amol Ashok KHALATE, Eindhoven (NL); Pieter Johannes Gertrudis MEIJERS, Horst (NL); Maurice Willem Jozef Etiënne WIJCKMANS, Eindhoven (NL)

(73) Assignee: ASML NETHERLANDS B.V., Veldhoven (NL)

(21) Appl. No.: 18/862,991

(22) PCT Filed: Apr. 28, 2023
(86) PCT No.: PCT/EP2023/061255

§ 371 Date: Nov. 5, 2024

(30) Foreign Application Priority Data
May 31, 2022 (EP) 22176549.8

(51) Int. Cl. G03F 7/00

(52) U.S. Cl. CPC G03F 7/70525; G03F 7/705; G03F 7/70533

(57) ABSTRACT

A method for determining a failure event on a lithography system. The method includes decomposing at least one signal generated within the lithography system into a plurality of component signals, each component signal relating to a different respective frequency range; evaluating at least one of the component signals with respect to nominal lithographic system behavior; and identifying any deviation of at least one of the component signals from the nominal lithographic system behavior as a failure event.

### CROSS-REFERENCE TO RELATED APPLICATIONS

This application claims priority of EP application 22176549.8 which was filed on 31 May 2022 and which is incorporated herein in its entirety by reference.

### FIELD OF INVENTION

The present invention relates to methods and apparatus usable, for example, in the manufacture of devices by lithographic techniques, and to methods of manufacturing devices using lithographic techniques. The invention relates more particularly to failure detection for such devices.

### BACKGROUND ART

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. including part of a die, one die, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. These target portions are commonly referred to as “fields”.

In the manufacture of complex devices, typically many lithographic patterning steps are performed, thereby forming functional features in successive layers on the substrate. A critical aspect of performance of the lithographic apparatus is therefore the ability to place the applied pattern correctly and accurately in relation to features laid down (by the same apparatus or a different lithographic apparatus) in previous layers. For this purpose, the substrate is provided with one or more sets of alignment marks. Each mark is a structure whose position can be measured at a later time using a position sensor, typically an optical position sensor. The lithographic apparatus includes one or more alignment sensors by which positions of marks on a substrate can be measured accurately. Different types of marks and different types of alignment sensors are known from different manufacturers and different products of the same manufacturer.

In other applications, metrology sensors are used for measuring exposed structures on a substrate (either in resist and/or after etch). A fast and non-invasive form of specialized inspection tool is a scatterometer in which a beam of radiation is directed onto a target on the surface of the substrate and properties of the scattered or reflected beam are measured. Examples of known scatterometers include angle-resolved scatterometers of the type described in US2006033921A1 and US2010201963A1. In addition to measurement of feature shapes by reconstruction, diffraction based overlay can be measured using such apparatus, as described in published patent application US2006066855A1. Diffraction-based overlay metrology using dark-field imaging of the diffraction orders enables overlay measurements on smaller targets. Examples of dark field imaging metrology can be found in international patent applications WO 2009/078708 and WO 2009/106279 which documents are hereby incorporated by reference in their entirety. Further developments of the technique have been described in published patent publications US20110027704A, US20110043791A, US2011102753A1, US20120044470A, US20120123581A, US20130258310A, US20130271740A and WO2013178422A1. These targets can be smaller than the illumination spot and may be surrounded by product structures on a wafer. Multiple gratings can be measured in one image, using a composite grating target. The contents of all these applications are also incorporated herein by reference.

When a lithography system develops a fault, it is important to identify the cause of the fault as soon as possible. Presently, this is achieved by trying to reproduce the issue. The triggers for fault detection are based on time-domain signals.

It would be desirable to improve on such failure event detection methods.

### SUMMARY OF THE INVENTION

The invention in a first aspect provides a method for determining a failure event on a lithography system, the method comprising: decomposing at least one signal generated within the lithography system into a plurality of component signals, each component signal relating to a different respective frequency range; evaluating at least one of said component signals with respect to nominal lithographic system behavior; and identifying any deviation of at least one of said component signals from said nominal lithographic system behavior as a failure event.

The invention in a second aspect provides a signal deviation detection block operable to determine a failure event on a lithography system, comprising: one or more filters operable to decompose a signal generated within the lithography system into a plurality of component signals, each component signal relating to a different respective frequency range; and a processor operable to evaluate at least one of said component signals with respect to nominal lithographic system behavior; and identify any deviation of at least one of said component signals from said nominal lithographic system behavior as a failure event.

Also disclosed is a computer program being operable to perform the method of the first aspect.

The above and other aspects of the invention will be understood from a consideration of the examples described below.

### BRIEF DESCRIPTION OF THE DRAWINGS

Embodiments of the invention will now be described, by way of example only, with reference to the accompanying drawings, in which:

FIG. 1 depicts a lithographic apparatus;

FIG. 2 illustrates schematically measurement and exposure processes in the apparatus of FIG. 1;

FIG. 3 is a schematic drawing of a fault detection system comprising a plurality of fault detection modules according to an embodiment; and

FIG. 4 is a schematic drawing of a signal deviation detection block of a fault detection module according to a first embodiment;

FIGS. 5(a), 5(b), 5(c) and 5(d) each comprise a schematic drawing of a signal decomposer block of a signal deviation detection block according to different embodiments; and

FIG. 6 is a schematic drawing of a signal deviation detection block of a fault detection module according to a second embodiment.

### DETAILED DESCRIPTION OF EMBODIMENTS

Before describing embodiments of the invention in detail, it is instructive to present an example environment in which embodiments of the present invention may be implemented.

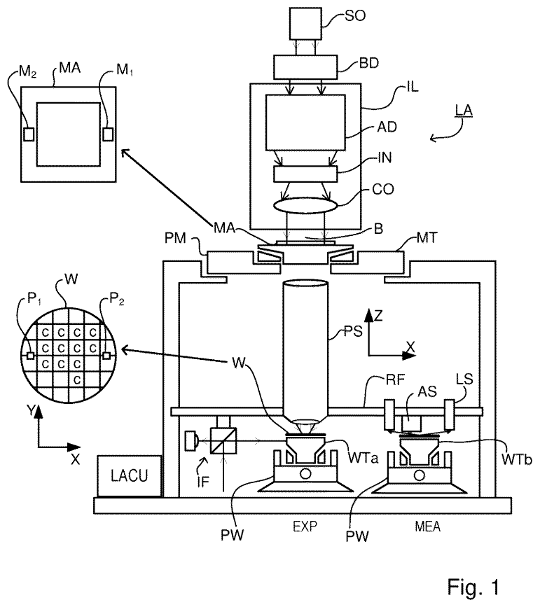

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation.

The patterning device support MT holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support MT may be a frame or a table, for example, which may be fixed or movable as required. The patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment marks may also be included within dies, in amongst the device features, in which case it is desirable that the markers be as small as possible and not require any different imaging or process conditions than adjacent features. The alignment system, which detects the alignment markers is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables WTa, WTb and two stations—an exposure station EXP and a measurement station MEA—between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

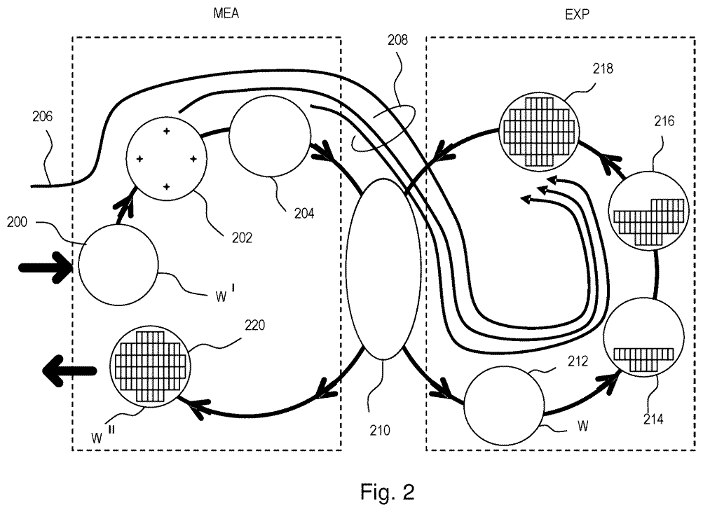

FIG. 2 illustrates the steps to expose target portions (e.g. dies) on a substrate W in the dual stage apparatus of FIG. 1. On the left hand side within a dotted box are steps performed at a measurement station MEA, while the right hand side shows steps performed at the exposure station EXP. From time to time, one of the substrate tables WTa, WTb will be at the exposure station, while the other is at the measurement station, as described above. For the purposes of this description, it is assumed that a substrate W has already been loaded into the exposure station. At step 200, a new substrate W′ is loaded to the apparatus by a mechanism not shown. These two substrates are processed in parallel in order to increase the throughput of the lithographic apparatus.

Referring initially to the newly-loaded substrate W′, this may be a previously unprocessed substrate, prepared with a new photo resist for first time exposure in the apparatus. In general, however, the lithography process described will be merely one step in a series of exposure and processing steps, so that substrate W′ has been through this apparatus and/or other lithography apparatuses, several times already, and may have subsequent processes to undergo as well. Particularly for the problem of improving overlay performance, the task is to ensure that new patterns are applied in exactly the correct position on a substrate that has already been subjected to one or more cycles of patterning and processing. These processing steps progressively introduce distortions in the substrate that must be measured and corrected for, to achieve satisfactory overlay performance.

The previous and/or subsequent patterning step may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation.

At 202, alignment measurements using the substrate marks P1 etc. and image sensors (not shown) are used to measure and record alignment of the substrate relative to substrate table WTa/WTb. In addition, several alignment marks across the substrate W′ will be measured using alignment sensor AS. These measurements are used in one embodiment to establish a “wafer grid”, which maps very accurately the distribution of marks across the substrate, including any distortion relative to a nominal rectangular grid.

At step 204, a map of wafer height (Z) against X-Y position is measured also using the level sensor LS. Conventionally, the height map is used only to achieve accurate focusing of the exposed pattern. It may be used for other purposes in addition.

When substrate W′ was loaded, recipe data 206 were received, defining the exposures to be performed, and also properties of the wafer and the patterns previously made and to be made upon it. To these recipe data are added the measurements of wafer position, wafer grid and height map that were made at 202, 204, so that a complete set of recipe and measurement data 208 can be passed to the exposure station EXP. The measurements of alignment data for example comprise X and Y positions of alignment targets formed in a fixed or nominally fixed relationship to the product patterns that are the product of the lithographic process. These alignment data, taken just before exposure, are used to generate an alignment model with parameters that fit the model to the data. These parameters and the alignment model will be used during the exposure operation to correct positions of patterns applied in the current lithographic step. The model in use interpolates positional deviations between the measured positions. A conventional alignment model might comprise four, five or six parameters, together defining translation, rotation and scaling of the ‘ideal’ grid, in different dimensions. Advanced models are known that use more parameters.

At 210, wafers W′ and W are swapped, so that the measured substrate W′ becomes the substrate W entering the exposure station EXP. In the example apparatus of FIG. 1, this swapping is performed by exchanging the supports WTa and WTb within the apparatus, so that the substrates W, W′ remain accurately clamped and positioned on those supports, to preserve relative alignment between the substrate tables and substrates themselves. Accordingly, once the tables have been swapped, determining the relative position between projection system PS and substrate table WTb (formerly WTa) is all that is necessary to make use of the measurement information 202, 204 for the substrate W (formerly W′) in control of the exposure steps. At step 212, reticle alignment is performed using the mask alignment marks M1, M2. In steps 214, 216, 218, scanning motions and radiation pulses are applied at successive target locations across the substrate W, in order to complete the exposure of a number of patterns.

By using the alignment data and height map obtained at the measuring station in the performance of the exposure steps, these patterns are accurately aligned with respect to the desired locations, and, in particular, with respect to features previously laid down on the same substrate. The exposed substrate, now labeled W″ is unloaded from the apparatus at step 220, to undergo etching or other processes, in accordance with the exposed pattern.

The skilled person will know that the above description is a simplified overview of a number of very detailed steps involved in one example of a real manufacturing situation. For example rather than measuring alignment in a single pass, often there will be separate phases of coarse and fine measurement, using the same or different marks. The coarse and/or fine alignment measurement steps can be performed before or after the height measurement, or interleaved.

In a lithography system, an important issue which has a significant impact on system up-time and is the ability to quickly and efficiently detect and/or diagnose events or trends (e.g., fault events) which might be indicative of irregular or abnormal behavior. However, such systems are very complex, comprising a number of different modules (e.g., including inter alia projection optics module, wafer stage module, reticle stage module, reticle masking module) each of which generate large amounts of data. Complex issues, involving multiple modules may be a particular challenge to diagnose due to a lack of data for the failure event. The complete context information (e.g., traces from all modules) at the moment of fault is typically unavailable.

To address this, one present method attempts to reproduce the issue (failure event) in order to collect the context information for diagnosis. This is very time consuming and results in high down-time, particularly for (non-reproducible) intermittent issues. In addition, no cross-module failure event triggers are available; even when reproducing an issue, only single module information can be collected.

Furthermore, in present diagnostic methods, the triggers for fault event detection are based on time-domain signals. A trigger is typically generated when a specified signal crosses a predefined threshold. This is typically a time-domain anomaly detection based on sensor signal amplitude. Because of this, many faults exciting specific frequency bands are not captured. This may result in it taking a substantially long time to find a root cause, or even a failure to identify the root cause.

To address one or more of these issues, a method for determining a failure event on a lithography system is proposed. The method comprising the steps of: decomposing a signal generated within the lithography system into a plurality of component signals, each component signal relating to a different respective frequency range; evaluating each of said component signals with respect to nominal lithographic system behavior (e.g., comparing each of said component signals to an indicator of nominal lithographic system behavior); and identifying any deviation of at least one of said component signals from said nominal lithographic system behavior as a failure event. The indicator may be a threshold value for the component signal, or a reference signal for example.

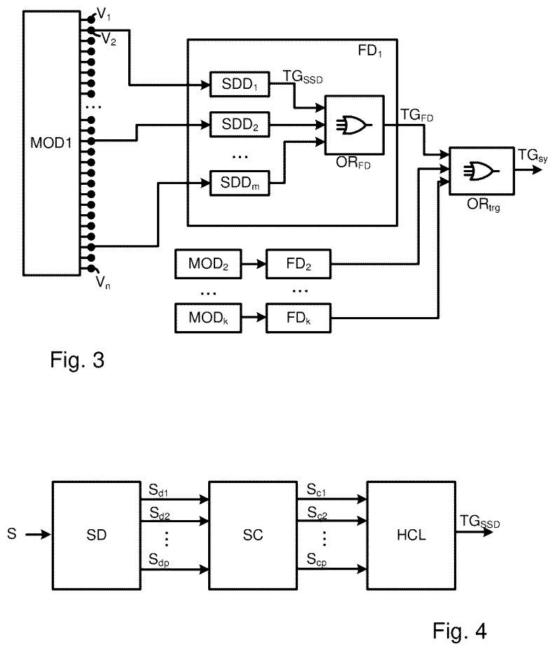

FIG. 3 is a high-level diagram of a proposed fault event trigger architecture according to an embodiment. Each lithographic system module MOD₁-MODₖ is provided with a respective fault detection module FD₁-FDₖ. Lithographic system module MOD₁ and its fault detection module FD₁ are shown in greater detail than the other modules. Each system module may generate a number of measurable signals, e.g., here the first lithographic system module MOD₁ generates n measurable signals V₁-Vₙ (the number of signals output from each lithographic system module MOD₁-MODₖ may vary). In an embodiment, each fault detection module FD₁-FDₖ may be configured for sampling a subset of the measurable signals generated by its respective lithographic system module MOD₁-MODₖ. In the example shown, each of m signals of a small subset of the n signals generated by lithographic system module MOD₁ is monitored by a respective signal deviation detection block SDD₁-SDDₘ of the fault detection module FD₁. The subset of monitored signals (e.g., m) may comprise fewer than 30%, fewer than 10%, fewer than 5%, fewer than 2% or fewer than 1% than the generated signals (e.g., n), and/or the number of monitored signals may be any proper subset of the generated signals.

The subset of monitored signals may be chosen on a per-module basis e.g., according to user or domain knowledge as to which signals are most relevant for system dynamics for a particular module. Alternatively or in addition, the monitored signals may be chosen on the basis of a particular system state. For example, the monitoring described herein may be performed primarily or only during certain pre-defined system states. The relevant signals for an exposure state (e.g., when the system is performing an exposure) may differ to those for a “TIS (transmission image sensor) scan” state (during which the actinic aerial image of the projected (TIS) reticle marks is measured). Therefore, the monitored signals can be selected based on the system state (the skilled person will recognize that there are many more system states than the two specific examples provided here). As such, the signals monitored by each fault detection module may be configurable, e.g., based on a particular state or action being performed by the system.

Each signal deviation detection block SDD₁-SDDₘ may comprise one or more suitable filters to define a plurality of component signals from the signal monitored by the signal deviation detection block, each component signal relating to a respective frequency range or frequency bin. As such, the monitoring of each monitored signal may be performed within frequency bins, such that, for example, if a deviation is detected within one or more frequency bins, an event trigger signal may be generated. Deviation may be detected by comparing a parameter (e.g., signal energy) of the signal component to a respective threshold value for the signal component. In this way complex frequency analysis can be done without complex computational implementations.

The outputs of each of the signal deviation detection blocks SDD₁-SDDₘ are combined into a single output, e.g., via a suitable logic operator. For example, an OR gate may be used to gate these outputs such that, should one (or more) of the signal deviation detection blocks generate a trigger TG_{SDD}, a corresponding fault event trigger TG_{FD} is generated by the fault detection module. Using an OR gate is only an example and other logic operations may be possible. For example, a particular two (or more) signal deviation detection blocks may be AND gated if appropriate for their respective signals; the output of the AND gate may then be OR gated (or otherwise combined) with the outputs of the other signal deviation detection blocks. This is a single specific example and the skilled person will recognize that any type, number and combination of logic operations may be used.

The outputs of the fault detection modules may be similarly combined with a suitable logic gate, e.g., an OR gate or combination of logic operations/gates, to generate a system fault event trigger signal TG_{SY} should (for example) one of the fault detection modules detect a fault and generate an FD trigger TG_{FD}.

FIG. 4 is an example schematic of a signal deviation detection block according to an embodiment. At a high level, the signal deviation detection block may comprise a signal decomposer block SD, a signal comparator block SC and a logic block or health check logic block HCL.

The signal decomposer block SD decomposes an input signal S into a plurality of signal components S_{d1}-S_{dp}, each relating to a different frequency range or frequency bin. More specifically, the input time-domain signal S(t) is decomposed into multiple time-domain signals Sᵢ(t), i=1, . . . , p using a filter-bank. Each signal Sᵢ(t), i=1, . . . , p comprises information from original signal S(t) in a particular frequency range. Optionally, one of the signals Sᵢ(t), i=1, . . . , p may be obtained via a through path to monitor the full input signal S(t).

The signal comparator block compares each signal component S_{d1}-S_{dp} to a respective indicator of nominal lithographic system behavior such as a threshold or reference so as to determine whether that signal component (and optionally the full signal) is within specification. A respective comparison output signal S_{c1}-S_{cp} is output for each signal component S_{d1}-S_{dp}.

The health check logic block combines the comparison output signals S_{c1}-S_{cp} according to one or more logic operations so as to generate a trigger TG_{SDD} when appropriate (e.g., when at least one of the comparison output signals S_{c1}-Sₚ indicates that at least one of the signal component S_{d1}-S_{dp} is out of specification. As has already been described, the logic operations may comprise a single logic gate, such as a single OR gate, or a more complicated combination of logic gates.

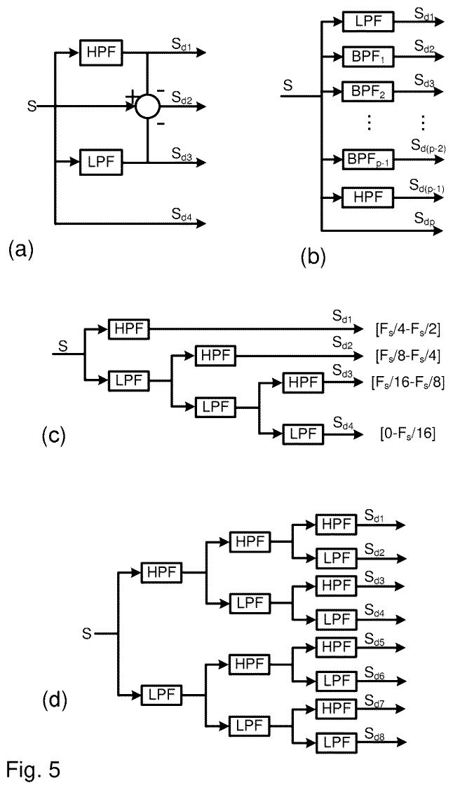

FIG. 5 shows four example embodiments of signal decomposer blocks SD usable in a signal deviation detection block such as illustrated in FIG. 4. FIG. 5(a) shows an example of a signal decomposer block which uses a high pass filter HPF and low pass filter LPF to obtain three signal components: a high frequency component covering an upper frequency range of the input signal S(t) obtained directly by application of high pass filter HPF on the input signal, a low frequency component covering a lower frequency range of the input signal S(t) obtained directly by application of low pass filter LPF on the input signal S(t) and an intermediate frequency component covering an intermediate frequency range obtained from removal of the high and low frequency components of the input signal from the input signal S(t). In this manner, three frequency bins are defined for signal monitoring. As mentioned above, an optional through path is provided to monitor the full input signal S(t).

FIG. 5(b) shows a second example of signal decomposer block and specifically an example filter bank to implement such a signal decomposer block. For some applications, depending on the nature of fault or system behavior, it may be necessary to define frequency ranges of varying length. The arrangement shown here comprises one or more band-pass filters BPF₁-BPFₚ₋₁ may be provided to provide flexibility to define such different frequency ranges. These band-pass filters may be implemented in combination with a low-pass filter LPF and high-pass filter HPF to define the highest and lowest frequency ranges, and if wanted, a through path as has been described.

For time-invariant signals (e.g. S(t)=A sin(ωt+ϕ) where A is amplitude, ω is 2πf and ϕ is phase), a frequency-domain analysis using fast Fourier transformation (FFT) analysis is sufficient. In such a case, for time-invariant signals, the signal decomposer block of FIG. 5(b) is capable of generating the required triggers.

However, for time-variant signals (e.g., S(t)=A sin(ω(t)*t+ϕ), where frequency content changes as a function of time, the signal decomposer block of FIG. 5(b) may not be sufficient. In this scenario, the examples illustrated in FIGS. 5(c) and 5(d) or variations thereon may be used instead. This is analogous to generating a trigger based on wavelet coefficients. In FIG. 5(c), in each layer, the low-passed signal from the previous layer (or the input signal for the first layer) is divided into two signals using a high-pass filter HPF and low pass filter LPF. The resultant frequency bin ranges (where Fₛ is the sampling frequency) is shown in this Figure. FIG. 5(d) shows an arrangement where each layer doubles the number of signal components using a high-pass filter HPF and low pass filter LPF on each component of the previous layer. Of course, fewer or more layers than shown in these Figures may be used.

It will be appreciated that, if certain faults are better monitored at a specific frequency, this can be achieved by using a suitable arrangement such as a Goertzel algorithm or tuned band-pass filter (e.g., in combination with any of the examples disclosed herein and/or within the scope of the disclosure).

Application of the filters may be achieved in real-time to enable in-line diagnostics.

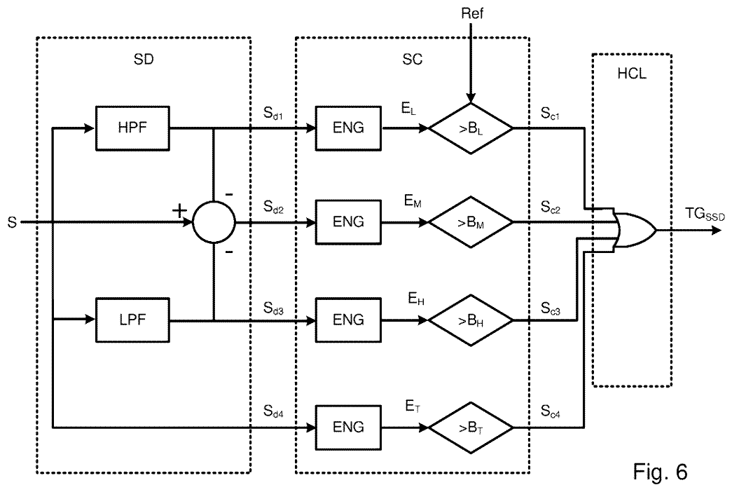

FIG. 6 is a specific implementation of signal deviation detection block according to an embodiment. This shows specific implementations of each of the signal decomposer block SD (e.g., that shown in FIG. 5(a)), the signal comparator block SC and the health check logic block HCL. The specific implementations of each of these blocks as shown here may be implemented with different specific implementations of the blocks as disclosed herein and/or within the scope of the disclosure. As such, the specific signal decomposer block SD shown here may be implemented with a different example of a signal comparator block and/or health check logic block HCL, the specific signal comparator block SC shown here may be implemented with a different example of a signal decomposer block SD and/or health check logic block HCL, etc.

In the signal comparator block SC, a monitoring metric calculation block ENG may be used to compute a particular monitoring parameter for each signal component. For example, the monitoring parameter may comprise the signal energy E_{L}, E_{M}, E_{H}, E_{T} of the respective signal component. Each of these energy values E_{L}, E_{M}, E_{H}, E_{T} may be compared to a respective reference value B_{L}, B_{M}, B_{H}, B_{T} e.g., which may be defined from an energy reference value Ref (e.g., Eᵢ_{_{N,ref}} below).

More generally, the signal comparator block SC can be used to evaluate whether the decomposed signal Sᵢ(t), i=1, . . . , p has deviated with respect to a reference for nominal or healthy behavior (or a subset of the components of the decomposed signal).

The energy Eᵢ_{_{N}} of the decomposed signal may be computed by squared sum error with respect to an offset/bias of the signal Sᵢ_{_{N,avg}}. where N is the sample of interest from the entire measurement of Sᵢ(t).

$${E}_{{i}_{N}} = \frac{1}{N} {\sum }_{j = 1}^{N} {( {s}_{i} [ j ] - {s}_{{i}_{N , a v g}} )}^{2} , i = 1 , … , p \qquad ( 1 )$$

The expected or reference energy Eᵢ_{_{N,ref}} of a decomposed signal corresponding to a healthy machine can be computed by collecting data from a healthy machine. A healthy machine may be defined as the machine state when system performance (e.g., overall system performance) is within specification.

The deviation ΔEᵢ_{_{N}} in a current measurement Eᵢ_{_{N}} with respect to the reference Eᵢ_{_{N,ref}} may be computed by as:

$$Δ {E}_{{i}_{N}} = 100 \frac{( {E}_{{i}_{N}} - {E}_{{i}_{N , ref}} )}{{E}_{{i}_{N , ref}}} , i = 1 , … , p \qquad ( 2 )$$

A threshold Bᵢ on the deviation in decomposed signal energy ΔEᵢ_{_{N}} may be defined using reference Eᵢ_{_{N,ref}} as:

$${B}_{i} = ( 1 + {θ}_{i} ) {E}_{{i}_{N , ref}} , i = 1 , … , p , \qquad ( 3 )$$

where θᵢ is the maximum allowed relative deviation with respect to Eᵢ_{_{N,ref}}. For example: if, for decomposed signal S₁, the maximum allowed relative deviation is 50% with respect to Eᵢ_{_{N,ref}} then θᵢ is 0.5 and if, for decomposed signal S₂, the maximum allowed relative deviation is 400% with respect to Eᵢ_{_{N,ref}} then θᵢ is 4.

The output comparator state S_{ci}, may be defined as 1 when threshold is crossed, and otherwise 0, i.e.;

$${S}_{ci} = 1 if Δ {E}_{{i}_{N}} > {B}_{i} , otherwise = 0 , i = 1 , … , p \qquad ( 4 )$$

Note that instead of comparing the energy of decomposed signal Si(t), the monitoring parameter may comprise the maximum value of Si(t) during N samples of interest.

It can be appreciated that each signal deviation detection block will monitor the signal health of several signals in real-time during system operation. Hence, it is desirable to keep computational demand from each signal deviation detection block as low as possible. In a specific example, computationally efficient first order low-pass and high-pass filters, which define respective low-pass and high pass signal components S_{LPF}[l], S_{HPF}[l], may be described by:

$${S}_{LPF} [ l ] = β S [ l ] + ( 1 - β ) S [ l - 1 ] ; β = {e}^{- 2 π \frac{{F}_{c}}{{F}_{s}}}$$

$${S}_{HPF} [ l ] = α ( S [ l ] - S [ l - 1 ] ) + α {S}_{HPF} [ l - 1 ] ; α = \frac{1}{2 π {F}_{c} / {F}_{s} + 1}$$

where F_{c} is the filter cut-off frequency and Fₛ is the sampling frequency.

In summary, a method is provided which provides signal deviation detection using frequency binning, which can capture a large set of faults not captured using existing methods. The methods also provide cross-module triggering to collect complete context information from all system modules.

It should be appreciated that the term color is used throughout this text synonymously with wavelength and the colors may include those outside the visible band (e.g., infrared or ultraviolet wavelengths).

While specific embodiments of the invention have been described above, it will be appreciated that the invention may be practiced otherwise than as described.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 1-100 nm), as well as particle beams, such as ion beams or electron beams.

The term “lens”, where the context allows, may refer to any one or combination of various types of optical components, including refractive, reflective, magnetic, electromagnetic and electrostatic optical components. Reflective components are likely to be used in an apparatus operating in the UV and/or EUV ranges.

The breadth and scope of the present invention should not be limited by any of the above-described exemplary embodiments, but should be defined only in accordance with the following claims and their equivalents.

Other aspects of the invention are set out in the following numbered clauses:

1. A method for determining a failure event on a lithography system, the method comprising:
decomposing at least one signal generated within the lithography system into a plurality of component signals, each component signal relating to a different respective frequency range;
evaluating at least one of said component signals with respect to nominal lithographic system behavior; and
identifying any deviation of at least one of said component signals from said nominal lithographic system behavior as a failure event.
   2. A method as claimed in clause 1, wherein said evaluating step comprises evaluating each of said component signals with respect to nominal lithographic system behavior; 3. A method as claimed in clause 1 or 2, wherein said evaluating step comprises comparing each of said component signals to at least one indicator of nominal lithographic system behavior.
   4. A method as claimed in clause 3, wherein said at least one indicator comprises a respective threshold value or reference signal for each component signal.
   5. A method as claimed in any preceding clause, comprising combining the outputs of said evaluating and identifying steps relating to each component signal to generate a failure event trigger signal for said at least one signal based on the identification of any deviation of at least one of said component signals.
   6. A method as claimed in clause 5, comprising:
performing said method separately for each signal of a plurality of signals relating to a lithographic system module of said lithographic system; and
combining the failure event trigger signals for each signal of the plurality of signals relating to the lithographic system module to generate a failure event trigger signal for said lithographic system module.
   7. A method as claimed in clause 6, wherein said plurality of signals comprise a subset of measurable signals generated by said lithographic system module.
   8. A method as claimed in clause 7, comprising selecting said subset of measurable signals based on one or both of: domain knowledge and a system state of the lithographic system.
   9. A method as claimed in clause 6, 7 or 8 comprising:
performing said method separately for each lithographic system module of a plurality of lithographic system modules relating to the lithographic system; and
combining the failure event trigger signals relating to each lithographic system module to generate a failure event trigger signal for said lithographic system.
   10. A method as claimed in any of clauses 5 to 9, wherein, in one or more of said combining steps, said outputs are combined using one or more logic operators.
   11. A method as claimed in clause 10, wherein said one or more logic operators comprises at least an OR operator.
   12. A method as claimed in any preceding clause, wherein said decomposing step comprises applying one or more high-pass, low-pass and/or band-pass filters to said at least one signal.
   13. A method as claimed in clause 12, wherein said decomposing step comprises applying one or more layers of at least a low-pass filter and a high-pass filter to the signal or signals of a previous layer.
   14. A method as claimed in clause 11, wherein said decomposing step comprises applying at least a low-pass filter and a high-pass filter to said at least one signal so as to generate at least three said signal components: a low frequency component covering a lower frequency range of the at least one signal, a high frequency component covering an upper frequency range of the at least one signal and an intermediate frequency component covering an intermediate frequency range of the at least one signal, between said lower frequency range and upper frequency range.
   15. A method as claimed in any preceding clause, wherein said decomposing step comprises applying at least one Goertzel algorithm or band-pass filter to said at least one signal so as to generate a signal component at a specific frequency or specific frequency range.
   16. A method as claimed in any preceding clause, comprising a step of evaluating the at least one signal, undecomposed, with respect to nominal lithographic system behavior; and identifying any deviation of said at least one signal from said nominal lithographic system behavior as a failure event.
   17. A method as claimed in any preceding clause, wherein said step of evaluating said component signals comprises evaluating a signal energy of said component signals.
   18. A signal deviation detection block operable to determine a failure event on a lithography system, comprising:
one or more filters operable to decompose a signal generated within the lithography system into a plurality of component signals, each component signal relating to a different respective frequency range; and
a processor operable to evaluate at least one of said component signals with respect to nominal lithographic system behavior, and identify any deviation of at least one of said component signals from said nominal lithographic system behavior as a failure event.
   19. A signal deviation detection block as claimed in clause 18, wherein said processor is operable to evaluate each of said component signals with respect to nominal lithographic system behavior.
   20. A signal deviation detection block as claimed in clause 18 or 19, wherein said processor is operable to compare each of said component signals to at least one indicator of nominal lithographic system behavior.
   21. A signal deviation detection block as claimed in clause 20, wherein said at least one indicator comprises a respective threshold value or reference signal for each component signal.
   22. A signal deviation detection block as claimed in any of clauses 18 to 21, comprising one or more logic operators being operable to combine the outputs of said evaluating and identifying steps relating to each component signal to generate a failure event trigger signal for said signal based on the identification of any deviation of at least one of said component signals.
   23. A signal deviation detection block as claimed in clause 22, wherein said one or more logic operators comprises at least an OR operator
   24. A signal deviation detection block as claimed in any of clauses 18 to 23, wherein said one or more filters comprise one or more high-pass, low-pass and/or band-pass filters.
   25. A signal deviation detection block as claimed in clause 24, wherein said one or more filters comprise one or more layers of at least a low-pass filter and a high-pass filter.
   26. A signal deviation detection block as claimed in any of clauses 18 to 20, wherein said one or more filters comprise at least a low-pass filter and a high-pass filter arranged to generate at least three said signal components: a low frequency component covering a lower frequency range of the signal, a high frequency component covering an upper frequency range of the signal and an intermediate frequency component covering an intermediate frequency range of the signal, between said lower frequency range and upper frequency range.
   27. A signal deviation detection block as claimed in any of clauses 18 to 26, comprising a Goertzel algorithm or tuned band-pass filter operable to generate a signal component at a specific frequency or range of specific frequencies.
   28. A signal deviation detection block as claimed in any of clauses 18 to 27, wherein the processor is further operable to evaluate the signal, undecomposed, with respect to nominal lithographic system behavior; and identify any deviation of said signal from said nominal lithographic system behavior as a failure event.
   29. A signal deviation detection block as claimed in any of clauses 18 to 28, wherein said processor is operable to evaluate a signal energy of said component signals.
   30. A fault detection module operable to determine a failure event on a lithography system comprising:
a plurality of signal deviation detection blocks as claimed in any of clauses 18 to 29, each signal deviation detection block being operable to determine a failure event for a respective signal of a plurality of signals relating to a lithographic system module of said lithographic system; and
at least one logic operator operable to combine the outputs of each signal deviation detection block to generate a failure event trigger signal for said lithographic system module.
   31. A fault detection module as claimed in clause 30, wherein said at least one logic operator operable to combine the outputs of each signal deviation detection block comprise at least an OR operator.
   32. A fault detection module as claimed in clause 30 or 31, wherein said plurality of signals comprise a subset of measurable signals generated by said lithographic system module.
   33. A fault detection system operable to determine a failure event on a lithography system, comprising:
a plurality of fault detection modules as claimed in clause 30, 31 or 32, each fault detection module being operable to determine a failure event for a respective lithographic system module of said lithographic system;
at least one logic operator operable to combine the outputs of each fault detection module to generate a failure event trigger signal for said lithographic system.
   34. A fault detection system as claimed in clause 33, wherein said one or more logic operators operable to combine the outputs of each fault detection module comprises at least an OR operator.
   35. A computer program comprising program instructions operable to perform the method of any of any of clauses 1 to 15, when run on a suitable apparatus.
   36. A non-transient computer program carrier comprising the computer program of clause 35.
   37. A processing arrangement comprising:
the non-transient computer program carrier of clause 36; and
a processor operable to run the computer program comprised on said non-transient computer program carrier.
   38. A lithographic system comprising the fault detection system of clause 33 or 34.

1. A method for determining a failure event on a lithography system, the method comprising:
decomposing, by a hardware computer system, at least one signal generated within the lithography system into a plurality of component signals, each component signal relating to a different respective frequency range;
evaluating at least one of the component signals with respect to nominal lithographic system behavior; and
identifying any deviation of at least one of the component signals from the nominal lithographic system behavior as a failure event.

2. The method as claimed in claim 1, wherein the evaluating comprises evaluating each of the component signals with respect to nominal lithographic system behavior.

3. The method as claimed in claim 1, further comprising combining the outputs of the evaluating and identifying relating to each component signal to generate a failure event trigger signal for the at least one signal based on the identification of any deviation of at least one of the component signals.

4. The method as claimed in claim 3, comprising:
performing the method separately for each signal of a plurality of signals relating to a lithographic system module of the lithographic system; and
combining the failure event trigger signals for each signal of the plurality of signals relating to the lithographic system module to generate a failure event trigger signal for the lithographic system module.

5. The method as claimed in claim 4, wherein the plurality of signals comprise a subset of measurable signals generated by the lithographic system module.

6. The method as claimed in claim 5, further comprising selecting the subset of measurable signals based on domain knowledge, a system state of the lithographic system, or both.

7. The method claimed in claim 4, further comprising:
performing the method separately for each lithographic system module of a plurality of lithographic system modules relating to the lithographic system; and
combining the failure event trigger signals relating to each lithographic system module to generate a failure event trigger signal for the lithographic system.

8. The method as claimed in claim 4, wherein, in one or more of the combining steps, the outputs are combined using one or more logic operators.

9. The method as claimed in claim 1, wherein the decomposing comprises applying one or more high-pass, low-pass and/or band-pass filters to the at least one signal.

10. The method as claimed in claim 1, wherein the decomposing comprises applying at least one Goertzel algorithm or band-pass filter to the at least one signal so as to generate a signal component at a specific frequency or specific frequency range.

11. The method as claimed in claim 1, wherein the evaluating the component signals comprises evaluating a signal energy of the component signals.

12. A signal deviation detection block operable to determine a failure event on a lithography system, the block comprising:
one or more filters operable to decompose a signal generated within the lithography system into a plurality of component signals, each component signal relating to a different respective frequency range; and
a processor configured to evaluate at least one of the component signals with respect to nominal lithographic system behavior, and identify any deviation of at least one of the component signals from the nominal lithographic system behavior as a failure event.

13. The signal deviation detection block as claimed in claim 12, wherein the processor is configured to evaluate each of the component signals with respect to nominal lithographic system behavior

14. The signal deviation detection block as claimed in claim 12, comprising one or more logic operators configured to combine the outputs of the evaluation and identification relating to each component signal to generate a failure event trigger signal for the signal based on the identification of any deviation of at least one of the component signals.

15. The signal deviation detection block as claimed in claim 12, further comprising a Goertzel algorithm or tuned band-pass filter configured to generate a signal component at a specific frequency or range of specific frequencies.

16. The signal deviation detection block as claimed in claim 12, wherein the processor is configured to evaluate a signal energy of the component signals.

17. A fault detection module operable to determine a failure event on a lithography system, the module comprising:
a plurality of signal deviation detection blocks as claimed in claim 12, each signal deviation detection block configured to determine a failure event for a respective signal of a plurality of signals relating to a lithographic system module of the lithographic system; and
at least one logic operator configured to combine the outputs of each signal deviation detection block to generate a failure event trigger signal for the lithographic system module.

18. A fault detection system operable to determine a failure event on a lithography system, the system comprising:
a plurality of fault detection modules as claimed in claim 17, each fault detection module configured to determine a failure event for a respective lithographic system module of the lithographic system;
at least one logic operator configured to combine the outputs of each fault detection module to generate a failure event trigger signal for the lithographic system.

19. (canceled)

20. A non-transient computer program carrier comprising a computer program stored therein, the computer program, when executed by an apparatus, configured to cause the apparatus to at least perform the method of claim 19.

21. A processing arrangement comprising:
the non-transient computer program carrier of claim 20; and
a processor configured to run the computer program comprised on the non-transient computer program carrier.

22. A lithographic system comprising the fault detection system of claim 18.
